(19) United States
(12) Patent Application Publication
(10) Pub. No.: US 2008/0160725 A1
(43) Pub. Date: Jul. 3, 2008

(54) SEMICONDUCTOR DIE PICK UP APPARATUS AND METHOD THEREOF

(75) Inventors: Hak-Kyoon BYUN, Chungcheongnam-do (KR); Hyun-Jung SONG, Gyeonggi-do (KR); Jong-Bo SHIM, Chungcheongnam-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/959,299

(22) Filed: Dec. 18, 2007

(30) Foreign Application Priority Data
Dec. 29, 2006 (KR) 2006-0137510

(51) Int. Cl. H01L 21/304; H01L 21/683

(52) U.S. Cl. 438/464; 156/379.8; 257/E21.238

(57) ABSTRACT

According to example embodiments, an apparatus for picking up a semiconductor die includes an electromagnetic collet unit configured to selectively generate an attractive force between the electromagnetic collet unit and a magnetic wafer adhesive tape disposed on a surface of the semiconductor die. The apparatus further includes a transfer head unit attached to the electromagnetic collet unit, the transfer head unit structured to move the semiconductor die picked up by the collet unit through a drive of a drive device.

### CROSS REFERENCE TO RELATED APPLICATIONS

This application claims priority under 35 U.S.C. §119 from Korean Patent Application 10-2006-0137510, filed on 29 Dec. 2006, the contents of which are hereby incorporated by reference in their entirety for all purposes as if fully set forth herein.

### BACKGROUND

1. Technical Field

This disclosure relates to semiconductor die pickup apparatus and methods, and more particularly, to semiconductor die pickup apparatus and methods that are capable of substantially reducing physical damage and pickup error on a semiconductor die and enhancing fidelity and throughput.

2. Description of the Related Art

The rapid technical development of semiconductor devices has coincided with the rapid development of the information communication field and rapid popularization of information media such as computers. The development requires a high-speed operation in a functional aspect or a large capacity of storage. The trend towards large capacity and high density in semiconductor devices increases the integration level of semiconductor devices and so the size of respective unit devices constituting a memory cell is also miniaturized. Accordingly, technologies for forming a highly integrated multilayer structure in a limited area have been an area of intense research.

Unit processes to fabricate semiconductor devices require extreme precision to correspond to such high integration technology. In general, unit processes to manufacture semiconductor devices may be largely divided into an impurity ion implantation and diffusion processes, deposition processes, etching processes (including photolithography), and wafer cleaning processes including CMP (Chemical Mechanical Polishing) to remove impurities, etc. The impurity ion implantation and diffusion is to implant impurity ions of group 3B, e.g., boron (B), or group 5B, e.g., phosphorus (P) or arsenic (As), into the interior of a semiconductor substrate. The deposition process is for forming a material film on a semiconductor substrate. The etching process including the photolithography is to pattern the material film formed through the thin film deposition into a given pattern. The wafer cleaning process including the CMP is to deposit an interlayer insulation layer, etc., on a wafer and to overall polish the surface of wafer to remove a step coverage. Such unit processes are performed selectively and repetitively, thereby stacking a plurality of circuit patterns on the surface of wafer to fabricate semiconductor devices.

Semiconductor devices completed in such unit processes undergo a sawing process of separating by the piece the semiconductor devices as semiconductor dies formed on the wafer into respective semiconductor dies by using a blade, so as to be assembled into a semiconductor integrated circuit. In the sawing process, one side of wafer is completely cut along a scribe line of one side direction in an entire face of the wafer, by using the blade. Then, a wafer chuck on which the wafers are mounted rotates by 90°, and the wafers are cut in a direction perpendicular to the initial cut, so that the wafers are separated into respective semiconductor dies. But, in such a sawing process, when only the wafer is sawed, the semiconductor chips are scattered and become lost outside the process area. To prevent this problem, an adhesive tape is usually adhered to a rear face of the wafer so that semiconductor chips separated from the wafer by the sawing process are still maintained in close relationship by the adhesive tape and are not scattered. The separated chips are then individually separated from the adhesive tape and undergo a packaging process for semiconductor chips.

FIGS. 1A to 1C illustrate steps of picking up sawed-semiconductor dies using a semiconductor die pickup apparatus according to a conventional art. Referring to FIG. 1A, adhesive tape 16 comprised of a base film 10, UV film 12 and adhesive film 14 adheres to a rear face of the wafer 18. The base film 10 may have a shape of dicing tape, and the adhesive film 14 functions as a main adhesive film to strongly fix the wafer 18 to the adhesive tape 16. The UV film 12 is a material film constructed of very sticky material to increase an adhesive force between the base film 10 and the adhesive film 14. The wafer 18, whose rear face adheres to the adhesive tape 16, is cut along a scribe line through use of a blade and sawed into respective semiconductor dies. As a result of sawing through the wafer, a plurality of semiconductor dies formed on the wafer are separated into respective semiconductor dies 18a by cutting along a scribe line 20.

FIGS. 1B and 1C illustrate steps of picking up the sawed semiconductor die 18a by using the semiconductor die pickup apparatus of FIG. 1A. With reference to FIG. 1B, a semiconductor die pickup apparatus 22 is positioned over the wafer 18 to pick up the semiconductor die 18a cut and separated along the scribe line 20. The semiconductor die pickup apparatus 22 comprises a transfer head 28 that is connected to a drive device and that moves the semiconductor dies 18a piece by piece into processing equipment for a subsequent process. The semiconductor die pickup apparatus further includes a collet 24 that is affixed to a lower end of the transfer head 28 and that has vacuum lines 26 disposed within to create suction that will hold the sawed semiconductor die 18a against the collet 24. The collet 24 may be formed of, for example, a rubber material, to substantially reduce damage on the semiconductor die 18a. To more positively prevent damage of the semiconductor die 18a, a protection film formed of soft material may be additionally formed on a lower part of the collet 24.

Referring to FIG. 1C, the individually separated semiconductor dies 18a are raised by a plunge pin 30, where the raised semiconductor die 18a is picked up by the suction of the vacuum lines 26 and held against the collet 24.

Unfortunately, the semiconductor die pickup process referred to in FIGS. 1A to 1C is a push-up scheme that lifts plunge pins 30 against a back face of the semiconductor die 18a to raise the semiconductor die. The contact stress of the plunge pin 30 applied to the rear face of the semiconductor die 18a may cause cracks on a cut line area, indicated by the reference character A. For example, in the processing of an ultra-thin wafer under 50 μm, the sawed semiconductor dies cannot be efficiently separated with the plunge pin 30 due to the warpage or flexibility of the wafer 18, and cracks can form on the wafer when an excess force is applied to it.

Furthermore, in such a push-up scheme that pushes up a limited contact area of the semiconductor die 18a by using a plunge pin 30, a pushup force through the plunge pin is not evenly provided to an entire area of semiconductor die, thus causing a transformation of semiconductor die or pickup error, etc. For example, when pushing up the semiconductor die 18a by using plunge pin 30 in a state where an adherence between the semiconductor die and the adhesive film 14 is already generated as shown in a reference character B, the force of the plunge pin cannot reach the area B or the wafer 18 may be broken.

Also, when using the collet 24, the suction force applied to the semiconductor die 18a is concentrated in the vacuum lines 26 that are partially formed inside the collet. Thus, the suction force cannot evenly act over an entire area of semiconductor die 18a, which may also cause pickup error. Furthermore, the plunge pin 30 is fabricated according to the size of a semiconductor die that will be lifted by the plunge pin, thus requiring a dedicated semiconductor die pickup apparatus for different sizes of semiconductor die.

Example embodiments address these and other disadvantages of the conventional art.

### BRIEF DESCRIPTION OF THE DRAWINGS

The example embodiments will become more fully understood from the detailed description and the accompanying drawings that are presented for illustrative rather than limiting purposes.

FIGS. 1A to 1C illustrate steps of picking up a sawed semiconductor die by a semiconductor die pickup apparatus according to a conventional art.

FIG. 2 illustrates a wafer adhesive tape adhering to a back face of wafer according to an example embodiment.

FIG. 3 illustrates a process of converting a ferrite material into a paramagnetic substance to form a magnetic adhesive layer suitable for use with example embodiments.

FIGS. 4A to 4E illustrate a semiconductor die pickup apparatus and semiconductor die pickup processes according to example embodiments.

FIG. 5 is a flowchart describing some of the processes illustrated in FIGS. 4A to 4E.

FIGS. 6A to 6E illustrate a semiconductor die pickup apparatus and semiconductor die pickup processes according to other example embodiments.

FIG. 7 is a flowchart describing some of the processes illustrated in FIGS. 6A to 6E.

FIG. 8A to 8E illustrate a semiconductor die pickup apparatus and semiconductor die pickup processes according to other example embodiments.

FIG. 9 is a flowchart describing some of the processes illustrated in FIGS. 8A to 8E.

FIG. 10A to 10E illustrate a semiconductor die pickup apparatus and semiconductor die pickup processes according to other example embodiments.

FIG. 11 is a flowchart describing some of the processes illustrated in FIGS. 10A to 10E.

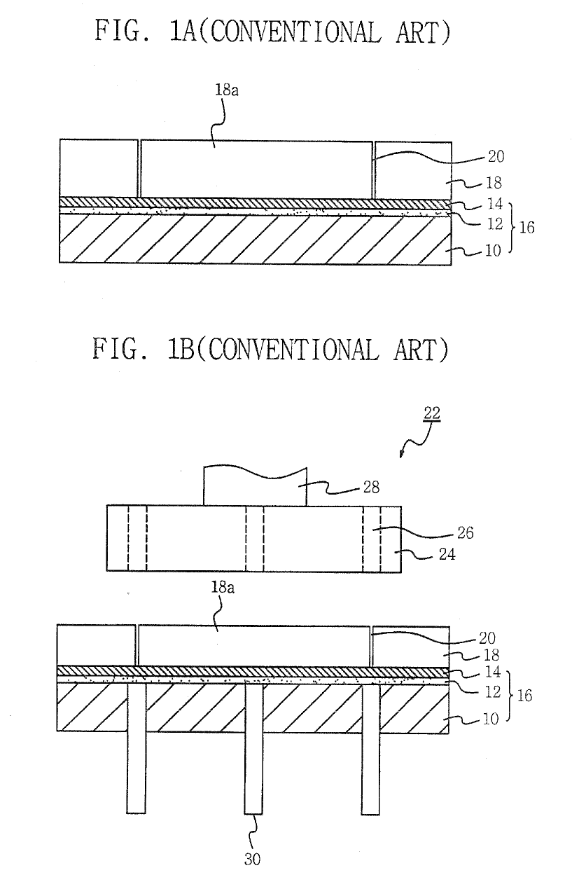

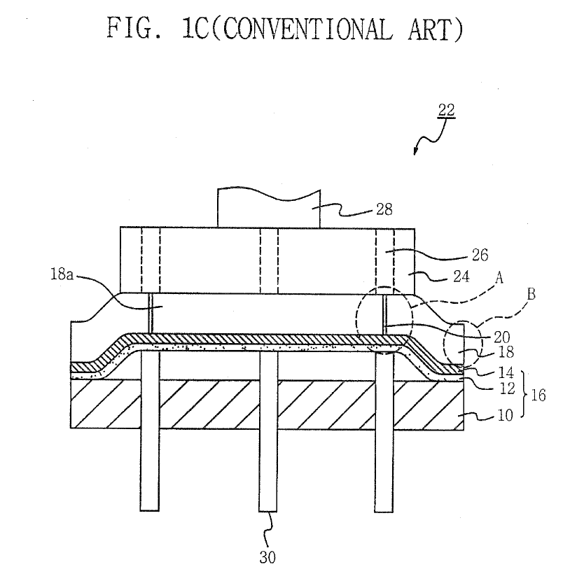

### DETAILED DESCRIPTION

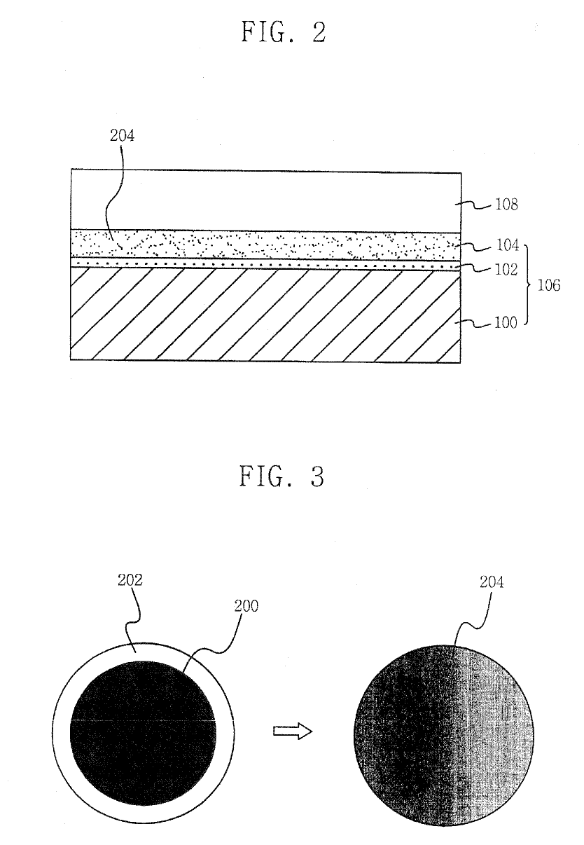

Example embodiments are described more fully hereinafter with reference to FIGS. 2 to 11. The invention, however, may be embodied in many different forms and should not be construed as limited to the example embodiments set forth herein. Rather, the example embodiments are provided so that this disclosure is thorough and complete, and fully conveys the inventive principles found in one or more example embodiments to those skilled in the art.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

FIG. 2 illustrates a wafer adhesive tape 106 adhering to a rear face of wafer 108 according to some example embodiments. The adhesive tape 106 includes a base film 100, an UltraViolet (UV) film 102, and a magnetic adhesive film 104. The magnetic adhesive film 104 includes magnetic filler 204 and so has properties of a paramagnetic substance or a ferromagnetic material. Thus, when electricity is applied to collet of the electromagnetic structure, attractive force is generated between the collet and the magnetic adhesive film 104, thereby separating a sawed semiconductor die from the base film 100.

Such principle of adding magnetic filler 204 to a general adhesive film so as to have a magnetic substance is explained below with reference to FIG. 3. FIG. 3 illustrates a process of converting a ferrite material into a paramagnetic substance to form a magnetic adhesive layer suitable for use with example embodiments. As shown on the left side of FIG. 3, a ferrite material 200 is surrounded by a material 202 containing O₂. Then, in a curing process performed by applying heat at a predetermined temperature, the ferrite material 200 is oxidized and changed into a paramagnetic substance or magnetic filler 204. The ferrite material 200 may be a material of electromagnetic structure that forms a magnetic field when electricity is applied, such as iron, nickel, cobalt etc.

In general, magnetic substances are materials that become magnetized in the presence of an externally applied magnetic field. Magnetic substances may be classified as ferromagnetic material, antiferromagnetic material, and paramagnetic material according to the level of magnetization exhibited in the presence of an external magnetic field.

Ferromagnetic materials are strong magnetic substances since a magnetic moment of the atoms are aligned. In antiferromagnetic material the magnetization is generated in a direction opposite to an external magnetic field.

Paramagnetic material is a substance where the magnetization is disordered by heat vibration of atoms. Paramagnetic material is magnetized weakly in the direction of the applied magnetic field and is not magnetized when the magnetic field is eliminated. The paramagnetic material may be, i.e., tin, platinum, iridium etc. in metal, and oxygen or air etc. The magnetic magnitude of the paramagnetic material is proportional to the magnitude of the external magnetic field, and a magnetization level is represented as a magnetic susceptibility. The magnetic susceptibility increases in inverse proportion to temperature and this is called the Curie's law.

As shown in FIG. 3, ferrite material 200 surrounded by material 202 containing O₂ is injected into the inside of general adhesive film, and then is cured at a given temperature. Once the ferrite material 200 oxidizes it has the properties of a paramagnetic material, and thus the general adhesive film becomes a magnetic adhesive film 104 that may be used as an element of adhesive tape 106, in accordance with example embodiments.

According to example embodiments, an adhesive tape 106 adhering to a rear face of wafer includes a magnetic adhesive film 104 that can be magnetized in a direction of an external magnetic field when electricity is applied to a collet of an electromagnetic structure to pick up a semiconductor die. Thus, an attractive force is generated between the collet and the magnetic adhesive film 104. Such attractive force acts as a constant detaching force on the magnetic adhesive film 104 and the UV film 102. As a result, a semiconductor die sawed from the overall wafer can be separated from the base film without damage. At this time, the attractive force is dispersed evenly over an entire area between the magnetic adhesive film and the collet. Thus, a constant pickup force also acts on the semiconductor die positioned on the magnetic adhesive film 104, thereby preventing a shape transformation of the semiconductor die and substantially reducing crack occurrence.

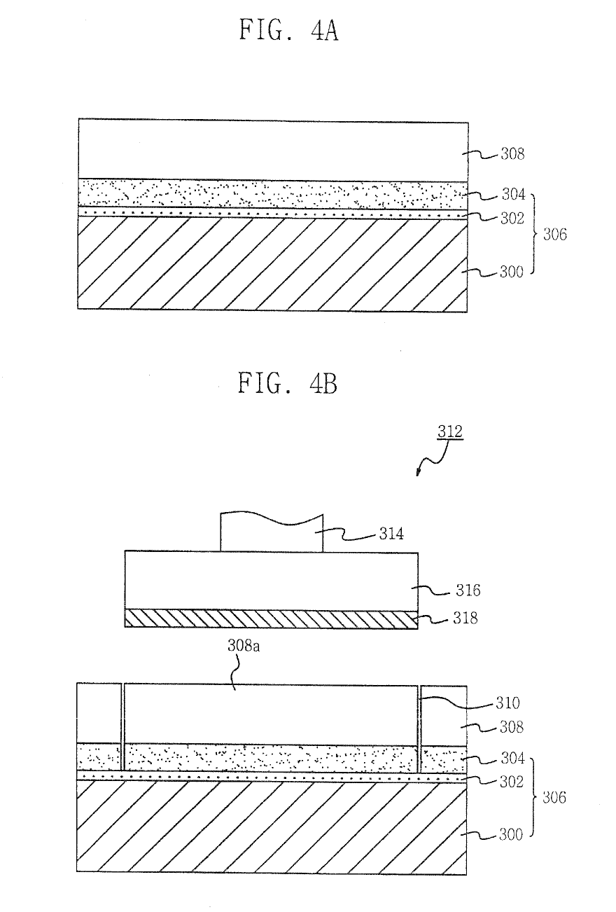

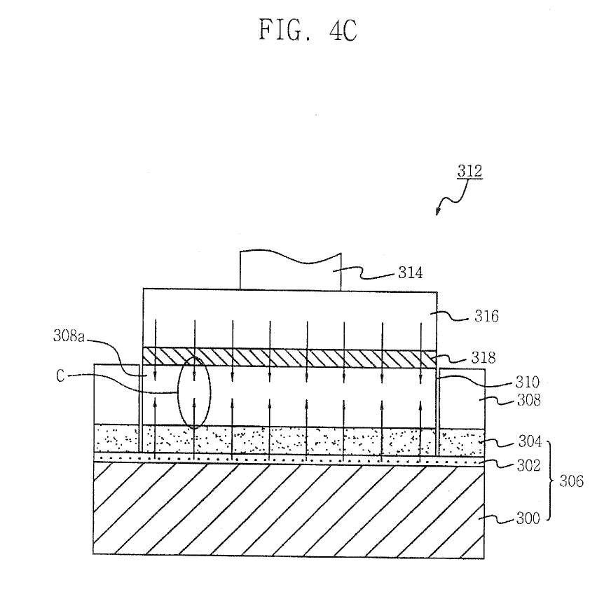

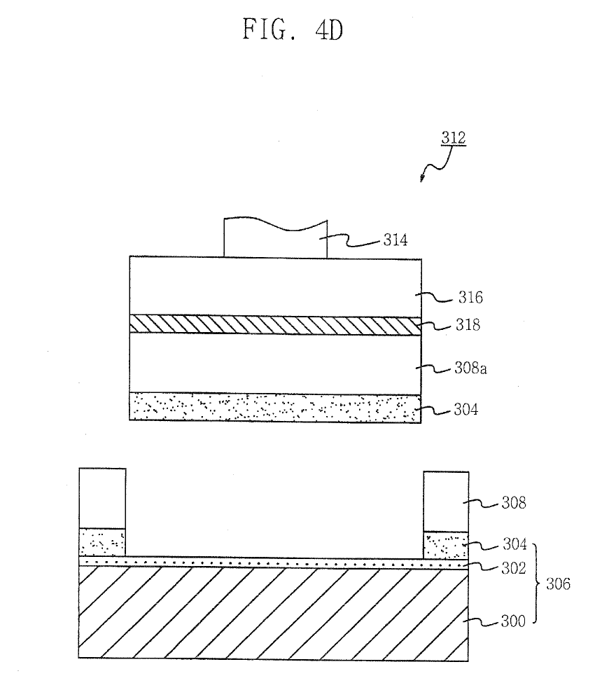

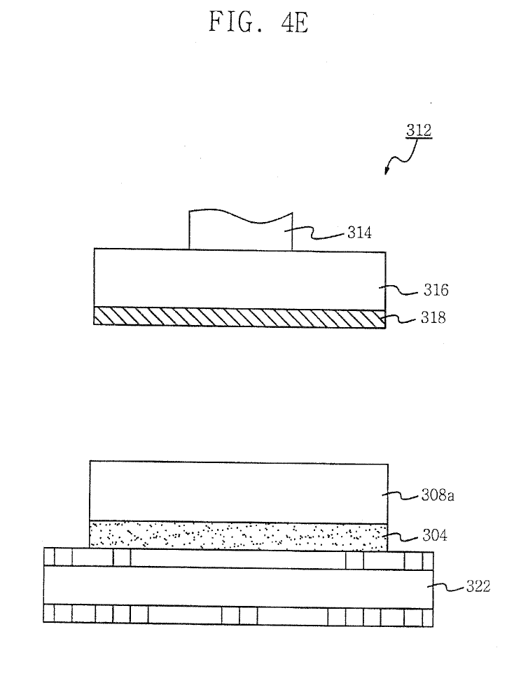

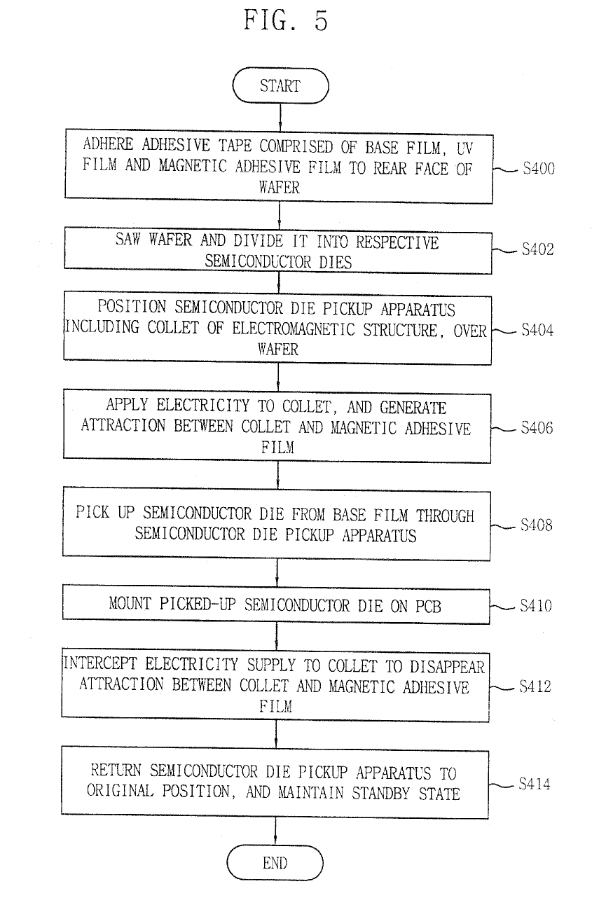

FIGS. 4A to 4E illustrate a semiconductor die pickup apparatus and semiconductor die pickup processes according to example embodiments. FIG. 5 is a flowchart describing some of the processes illustrated in FIGS. 4A to 4E.

Referring to FIGS. 4A and 5, an adhesive tape 306 constructed of a base film 300, UV film 302 and magnetic adhesive film 304 adheres to a rear face of wafer 308, in a step S400. The base film 300 has a shape of dicing tape, and the UV film 302 is a material layer formed of a very sticky material to increase an adhesive force between the base film 300 and the magnetic adhesive film 304. The magnetic adhesive film 304 strongly fixes the wafer 308 to the base film 300, and as was explained above is an important element of the semiconductor die adhesive tape 306 according to example embodiments.

In forming the magnetic adhesive film 304, ferrite material surrounded by material containing O₂, as magnetic substance, is injected into a general adhesive film, and then cured at a given temperature. The ferrite material may be a material of ferromagnetic structure that forms a magnetic field when electricity is applied, such as iron, nickel, cobalt etc. Then, in the curing step, the ferrite material is oxidized and takes on the properties of a paramagnetic substance, and is changed into magnetic adhesive film 304 having the properties of a paramagnetic substance. The oxidized ferrite material acts as a magnetic filler within the general adhesive filler, giving it paramagnetic properties.

As was explained above, the iron, nickel, cobalt, etc., are examples of a ferromagnetic substance. Therefore, in alternative example embodiments, the curing process may be eliminated and the properties of the ferromagnetic material can be used instead of the properties of paramagnetic material.

Referring to FIGS. 4B and 5, the wafer 308 is then sawed along a cut line 310 by using a blade, separating the multiple semiconductor dies 308a from the wafer, in a step S402. Subsequently, to pick up the semiconductor die 308a that are individually separated along the cut line 310, a semiconductor die pickup apparatus 312 according to example embodiments is positioned over the wafer 308 in a step S404. The semiconductor die pickup apparatus 312 includes a transfer head 314 and a collet 316. The transfer head 314 is connected to a drive device (not shown) that moves the sawed semiconductor die to a process equipment for a subsequent process. The collet 316 adheres to a lower end of the transfer head 314, and picks up the sawed semiconductor die 308a. A lower part of the collet 316 may be provided additionally with a protection film 318 formed of soft material to substantially reduce the damage on the semiconductor die 308a. According to example embodiments, the collet 316 of the semiconductor die pickup apparatus 312 preferably includes a magnetizable material. More particularly, the collet 316 preferably includes a metal material for forming a magnetic field when electricity is applied. The metal material may include, for example, iron, nickel, cobalt, etc., as ferromagnetic material of the ferrite group.

With reference to FIGS. 4C and 5, the semiconductor die pickup apparatus 312, including collet 316 with the electromagnetic structure, is positioned over the sawed semiconductor die 308a, and then electricity is applied to the collet 316. Then, in a step 406, the collet 316 of the electromagnetic structure is magnetized, and an attractive force is created between the collet 316 and the magnetic adhesive film 304 adhering to the rear face of the wafer 308, as referred to by the reference character C.

With reference to FIGS. 4D and 5, in the state that the attractive force acts between the collet 316 of electromagnetic structure and the magnetic adhesive film 304, the sawed semiconductor die 308a is picked up by using the transfer head 314 of the semiconductor die pickup apparatus 312, in a step S408. That is, the magnetic adhesive film 304 is separated from the UV film 302 through the attractive force acting between the collet 316 and the magnetic adhesive film 304, thereby separating the sawed semiconductor die 308a from the base film 300 and picking it up.

At this time, the magnetic filler is evenly distributed in the entire magnetic adhesive film 304. Magnetism is also evenly generated in the entire collet 316. Thus, a substantially even attractive force is distributed throughout an entire area of the magnetic adhesive film 304 and the collet 316, and a substantially even pickup force acts on the sawed semiconductor die 308a positioned on the magnetic adhesive film 304. Consequently, when picking up semiconductor die 308a by using the semiconductor die pickup apparatus 312, as shown in FIG. 4D, a substantially even detaching force acts on an entire area of the semiconductor die 308a, and the sawed semiconductor die 308a may be detached from the base film 300 without a transformation or crack on the semiconductor die 308a.

Referring to FIGS. 4E and 5, the picked-up semiconductor die 308a is moved to a Printed Circuit Board (PCB) 322 and mounted thereon in a step S410. Then, in a step S412, electrical input to the collet 316 is cut off, eliminating the magnetism of the collet 316 and the attractive force with the magnetic adhesive film 304. The sawed semiconductor die 308a remains on the PCB 322, constituting the circuit, and the semiconductor die pickup apparatus 312 returns to the original position and stands by for a subsequent semiconductor die pickup operation in a step S414.

As described above for the example embodiments, the magnetic adhesive film 304 contains magnetic filler that has a paramagnetic substance, and the collet 316 of electromagnetic structure having attractive force acting with the magnetic adhesive film 304, are used, thereby effectively separating sawed semiconductor die 308a from the base film without causing transformations or cracks.

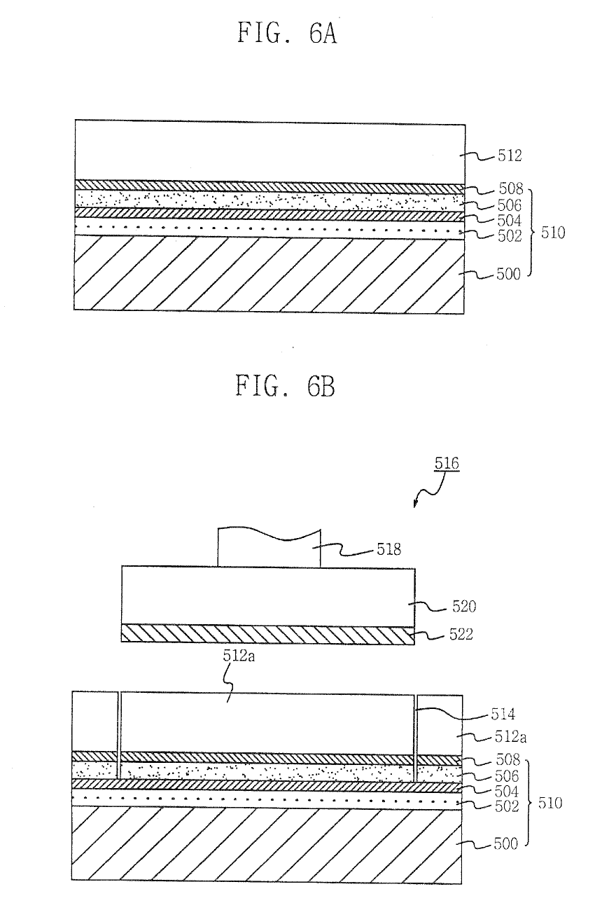

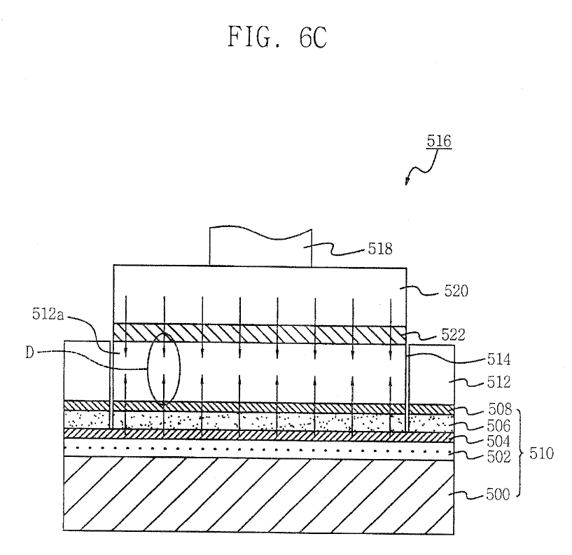

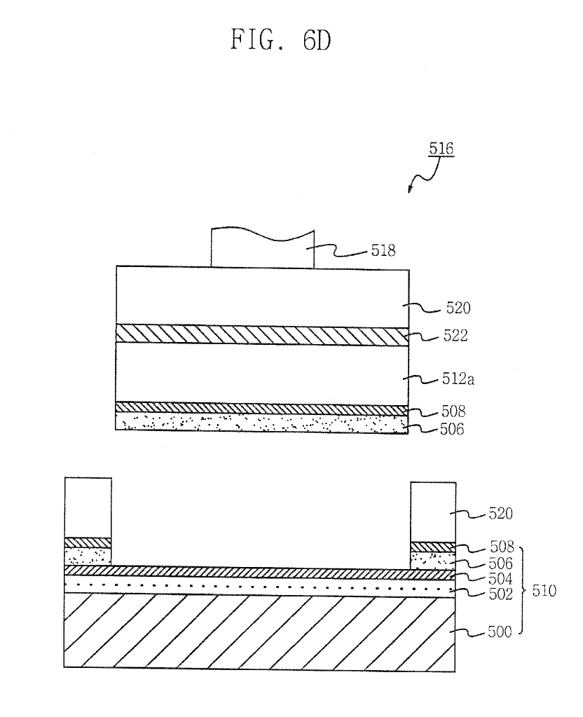

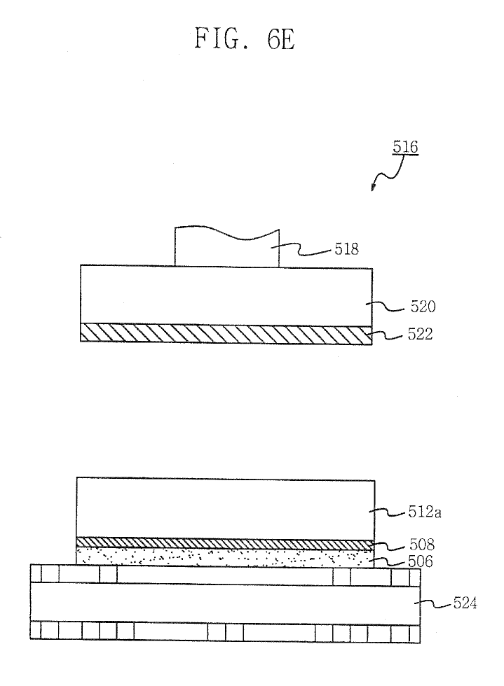

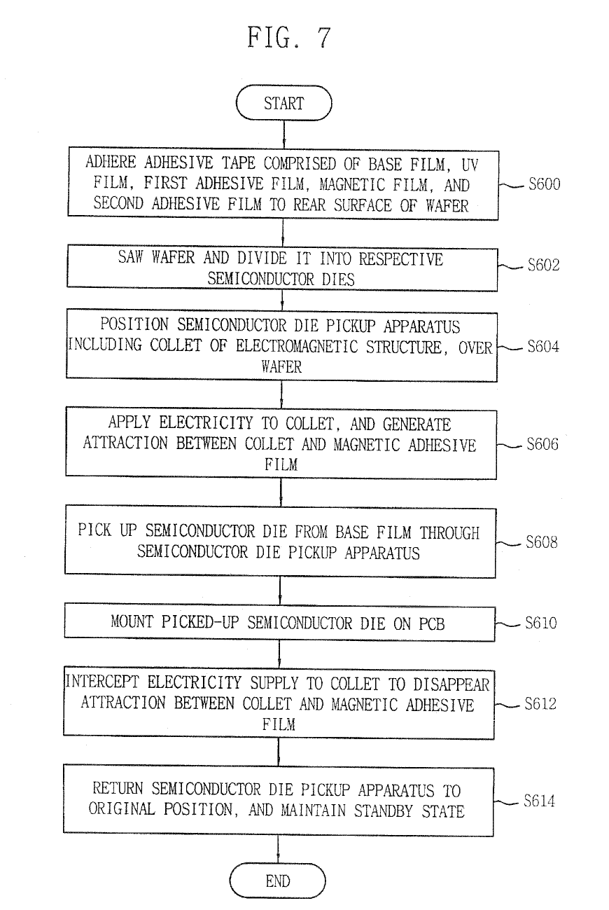

FIGS. 6A to 6E illustrate a semiconductor die pickup apparatus and semiconductor die pickup processes according to other example embodiments. FIG. 7 is a flowchart describing some of the processes illustrated in FIGS. 6A to 6E.

With reference to FIGS. 6A and 7, an adhesive tape 510, which is constructed of a base film 500, UV film 502, a first adhesive film 504, a magnetic adhesive film 506, and a second adhesive film 508, adheres to a rear face of wafer 512, in a step S600. The base film 500 has a shape of dicing tape, and the UV film 502 is a material layer formed of a very sticky material to increase an adhesive force between the base film 500 and the first adhesive film 504. The second adhesive film 508 functions as strongly fixing the wafer 512 to the base film 500. The magnetic adhesive film 506 is disposed between the first adhesive film 504 and the second adhesive film 508.

In forming the magnetic adhesive film 506, the first adhesive film 504 is formed on the UV film 502. Then, a general adhesive film is formed one layer more on the first adhesive film 504, and then ferrite material surrounded by material containing O₂, as a magnetic filler, is injected into the general adhesive layer, and then cured at a predetermined temperature. The ferrite material is oxidized in the cured step and so has a property of paramagnetic substance. Thus, the general adhesive film is changed into magnetic adhesive film 506 having the properties of a paramagnetic substance. The ferrite material may be material of electromagnetic structure that forms a magnetic field when electricity is applied, such as iron, nickel, cobalt etc.

On the other hand, the iron, nickel and cobalt etc. in itself are ferrite material having ferromagnetic substance. Thus, according to alternative embodiments the properties of ferromagnetic material can be used intact without the cure step.

According to the example embodiments described above, a general adhesive film is formed on the first adhesive film 504 and then ferrite material is injected into the general adhesive film so that it becomes a magnetic adhesive film. According to other example embodiments, the ferrite material layer may be formed to a given thickness directly on the first adhesive film 504. In this case, the ferrite material layer may be a material layer of an electromagnetic structure, such as iron, nickel, cobalt etc. that forms a magnetic field when electricity is applied.

Referring to FIGS. 6B and 7, a wafer 512 whose rear face adheres to the adhesive tape 510, is sawed along a scribe line of the wafer 512 by using blade. Then, in step S602, plural semiconductor dies formed on the wafer are separated into respective semiconductor dies 512a along a cut line 514 that is based on the scribe line.

Subsequently, to pick up the semiconductor dies 512a separated by the piece along the cut line 514, a semiconductor die pickup apparatus 516 according to example embodiments is positioned over the wafer 512 in a step S604. The semiconductor die pickup apparatus 516 comprises a transfer head 518 and a collet 520. The transfer head 518 is connected to a drive device that moves the transfer head and the sawed semiconductor die 512a to a process equipment for a subsequent process. The collet 520 adheres to a lower end of the transfer head 518, and picks up the sawed semiconductor die 512a. A lower part of the collet 520 may be provided additionally with a protection film 522 formed of soft material to substantially reduce the damage on the semiconductor die. The collet 520 of the semiconductor die pickup apparatus 516 preferably includes a magnetizable material. More particularly, the collet 520 includes a metal material for forming a magnetic field when electricity is applied, i.e., iron, nickel, cobalt, etc., as electromagnetic material from the ferrite group.

With reference to FIGS. 6C and 7, semiconductor die pickup apparatus 516 including collet 520 of the electromagnetic structure is positioned over the sawed semiconductor die 512a, and then electricity is applied to the collet 520. Then, the collet 520 of the electromagnetic structure is magnetized, and attractive force acts with magnetic adhesive film 506 adhering to the rear face of the wafer 512 as referred to as a reference character D, in a step S606.

With reference to FIGS. 6D and 7, when the attractive force acts between the collet 520 of electromagnetic structure and the magnetic adhesive film 506, the sawed semiconductor die 512a is picked up by using the transfer head 518 of the semiconductor die pickup apparatus 516, in a step S608. That is, the magnetic adhesive film 506 is separated from the first adhesive film 504 through the attractive force acting between the collet 520 and the magnetic adhesive film 506, thereby separating the sawed semiconductor die 512a from the base film 500 and picking it up.

At this time, magnetic filler is evenly distributed in the entire magnetic adhesive film 506. Magnetism is also evenly generated in the entire collet 520. An even attractive force acts through an entire area of the magnetic adhesive film 506 and the collet 520, and thus an even pickup force acts on the sawed semiconductor die 512a positioned on the magnetic adhesive film 506. Consequently, in picking up semiconductor die 512a by using the semiconductor die pickup apparatus 516, as shown in FIG. 6D, an even detaching force acts on an entire area of the semiconductor die 512a, whereby simply picking up the sawed semiconductor die 512a from the base film 500 does not generate a transformation or crack on the semiconductor die 512a.

Referring to FIGS. 6E and 7, the picked-up semiconductor die 512a is moved to PCB 524 and mounted thereon in a step S610. Then, electricity input to the collet 520 is intercepted. When the magnetism of the collet 520 is removed, the attractive force with the magnetic adhesive film 506 also disappears in a step S612. The sawed semiconductor die 512a remains on the PCB 524, constituting the circuit, and the semiconductor die pickup apparatus 516 returns to the original position and stands by for a subsequent semiconductor die pickup operation in a step S614.

According to the example embodiments describe above, the magnetic adhesive film 506 containing magnetic filler that has a paramagnetic substance, and the collet 520 of electromagnetic structure having attractive force with the magnetic adhesive film 506, are used, thereby effectively separating the sawed semiconductor die 512a from the base film without causing transformations or cracks.

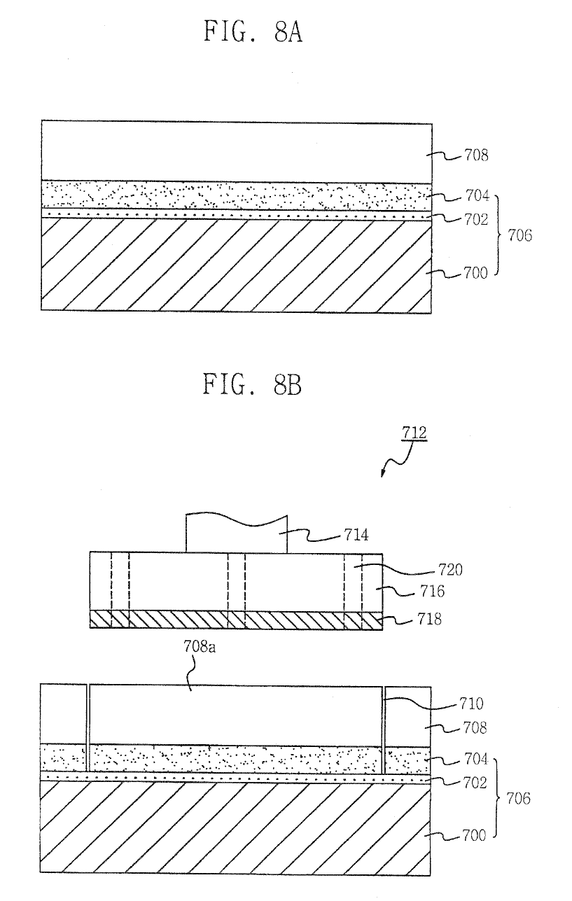

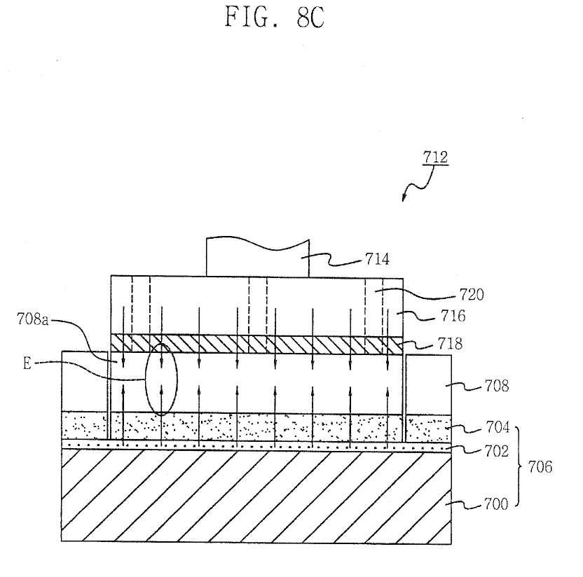

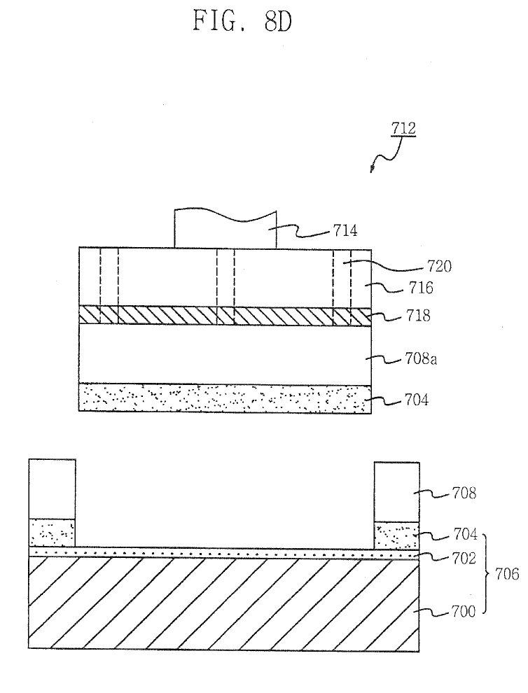

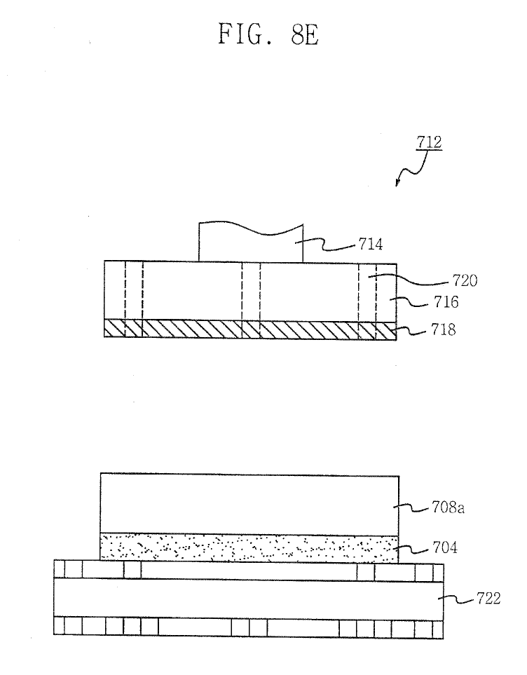

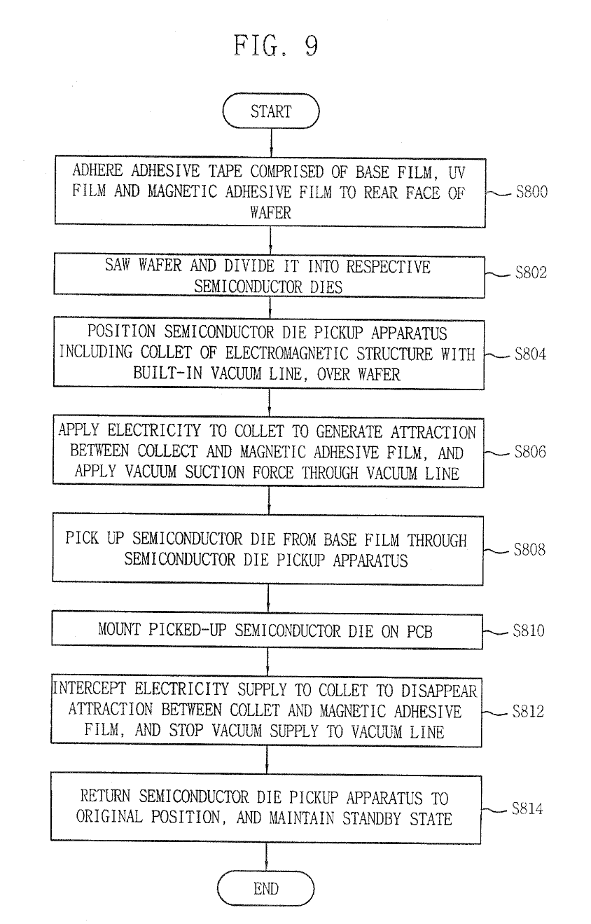

FIG. 8A to 8E illustrate a semiconductor die pickup apparatus and semiconductor die pickup processes according to other example embodiments. FIG. 9 is a flowchart describing some of the processes illustrated in FIGS. 8A to 8E.

With reference to FIGS. 8A and 9, an adhesive tape 706, which is constructed of a base film 700, UV film 702, and a magnetic adhesive film 704, adheres to a rear face of wafer 708, in a step S800. The base film 700 has a shape of dicing tape, and the UV film 702 is a material layer formed of a very sticky material to increase an adhesive force between the base film 700 and the magnetic adhesive film 704. The magnetic adhesive film 704 is a main adhesive film to strongly fix the wafer 708 to the base film 700.

In forming the magnetic adhesive film 704, ferrite material surrounded by material containing O₂, as magnetic substance, is injected into a general adhesive film, and then cured at a predetermined temperature. The ferrite material is oxidized in the cured step and so has a property of paramagnetic substance. Thus, the general adhesive film is changed into magnetic adhesive film 704 having the properties of paramagnetic substance. The oxidized ferrite material acts as magnetic filler that gives the general adhesive filler paramagnetic properties. The ferrite material may be material of electromagnetic structure forming a magnetic field when electricity is applied, such as iron, nickel, cobalt, etc.

On the other hand, the iron, nickel, cobalt etc. in itself are ferrite material having ferromagnetic substance. Thus, according to alternative example embodiments the properties of ferromagnetic material can be used intact without the cure step.

Referring to FIGS. 8B and 9, a wafer 708 whose rear face adheres to the adhesive tape 706, is sawed along a scribe line of the wafer 708 by using blade. Then, plural semiconductor dies formed on the wafer 708 are separated into respective semiconductor dies along a cut line based on the scribe line as reference number 710, in a step S802.

Subsequently, to pick up the semiconductor dies 708a separated by the piece along the cut line 710, a semiconductor die pickup apparatus 712 according to an embodiment of the invention is positioned over the wafer 708 in a step S804. The semiconductor die pickup apparatus 714 comprises a transfer head 714 and a collet 716. The transfer head 714 is connected to a drive device and moves by the piece the semiconductor die to a process equipment for a subsequent process. The collet 716 adheres to a lower end of the transfer head 714, and picks up the sawed semiconductor die. A lower part of the collet 716 may be provided additionally with a protection film 718 formed of soft material to substantially reduce the damage on the semiconductor die. It is herein a characteristic that the collet 716 of the semiconductor die pickup apparatus 712 is formed of magnetizable material. More particularly, the collet 716 is metal material for forming a magnetic field when electricity is applied, i.e., iron, nickel, or cobalt, etc., as electromagnetic material of ferrite group. Additionally, the collet 716 includes a plurality of vacuum lines 720 to apply suction to the sawed semiconductor die 708a positioned beneath the collet.

With reference to FIGS. 8C and 9, semiconductor die pickup apparatus 712 including collet 716 of the electromagnetic structure is positioned over the sawed semiconductor die 708a, and then electricity is applied to the collet 716. Then, the collet 716 of the electromagnetic structure is magnetized, and an attractive force acts with magnetic adhesive film 704 adhering to the rear face of the wafer 708 as referred to as a reference character E. Suction is supplied to the vacuum line 720 adapted inside the collet 716. As a result, attractive forces between the magnetized collet 716 and the magnetic adhesive Film 704 as well as a vacuum suction force through the vacuum line 720 act on the semiconductor die 718, in a step S806.

With reference to FIGS. 8D and 9, when the attractive force acts between the collet 716 of electromagnetic structure and the magnetic adhesive film 704, and the vacuum suction force through the vacuum line 720, act thereto, the sawed semiconductor die 718a is picked up by using the transfer head 714 of the semiconductor die pickup apparatus 712, in a step S808. That is, the magnetic adhesive film 704 is separated from the UV film 702 through the attractive force acting between the collet 716 and the magnetic adhesive film 704, thereby separating the sawed semiconductor die 708a from the base film 700 and picking it up.

Preferably, magnetic filler is evenly distributed throughout the entire magnetic adhesive film 704. Preferably, magnetism is also evenly generated in the entire collet 716. Consequently, an even attractive force acts through an entire area of the magnetic adhesive film 704 and the collet 716, and thus an even pickup force acts on the sawed semiconductor die 708a positioned on the magnetic adhesive film 704. Thus, when picking up semiconductor die 708a by using the semiconductor die pickup apparatus 712, as shown in FIG. 8D, an even detaching force acts on an entire area of the semiconductor die 708a, and the act of picking up the sawed semiconductor die 708a from the base film 700 does not generate a transformation or crack on the semiconductor die 708a.

Referring to FIGS. 8E and 9, the picked-up semiconductor die 708a is moved to PCB 722 and mounted thereon in a step S810. Then, electricity input to the collet 716 is intercepted. And then, a vacuum supply to the vacuum line 720 is stopped in a step S812. Then, the magnetism of the collet 716 disappears, and also the attractive force with the magnetic adhesive film 704 disappears. The vacuum suction force through the vacuum line 720 also disappears. The sawed semiconductor die 708a is separated from the semiconductor die pickup apparatus 712, and remains on the PCB 722, constituting the circuit. The semiconductor die pickup apparatus 712 returns to the original position and stands by for a subsequent semiconductor die pickup operation in a step S814.

According to the example embodiments described above, the magnetic adhesive film 704 containing magnetic filler that has a paramagnetic substance, and the collet 716 of electromagnetic structure having attractive force with the magnetic adhesive film 704, are used, thereby effectively separating the sawed semiconductor die 708a from the base film without causing transformations or cracks. Additionally, vacuum lines 720 are formed inside the collet 716, thus a pickup effect on the sawed semiconductor die 708a may be doubled as compared with depending upon only the attractive force with the magnetic adhesive film 704.

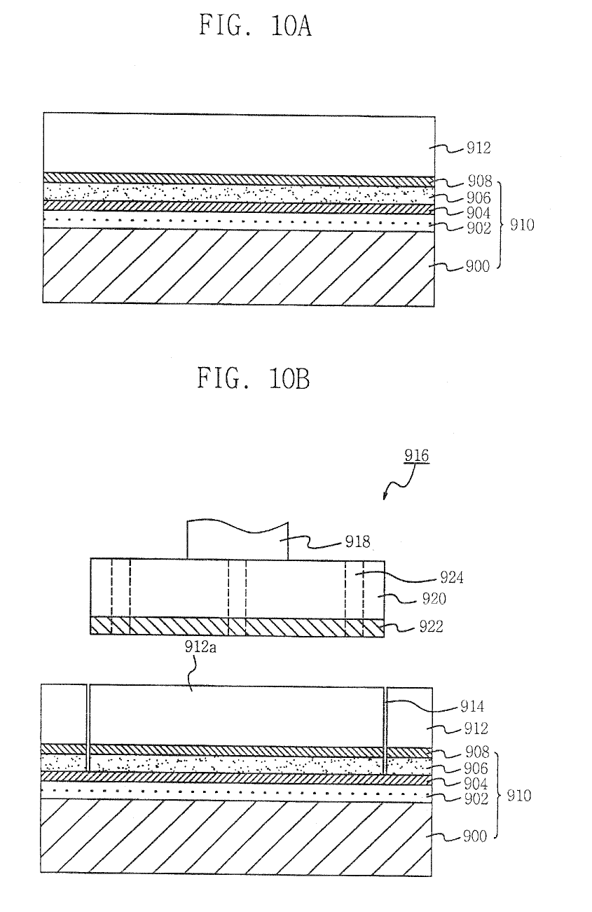

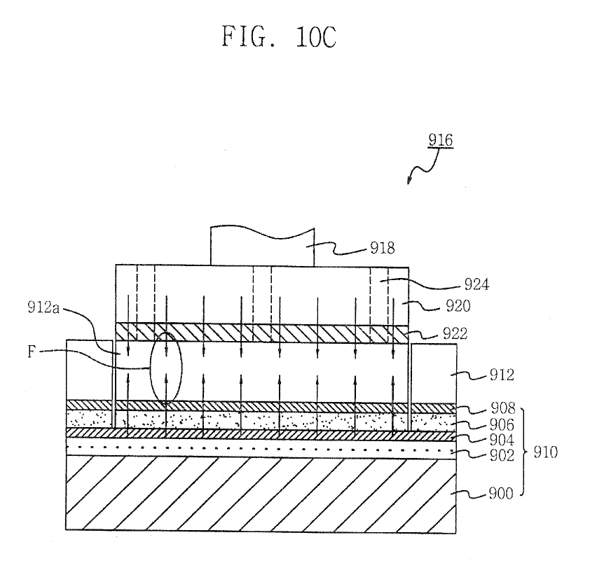

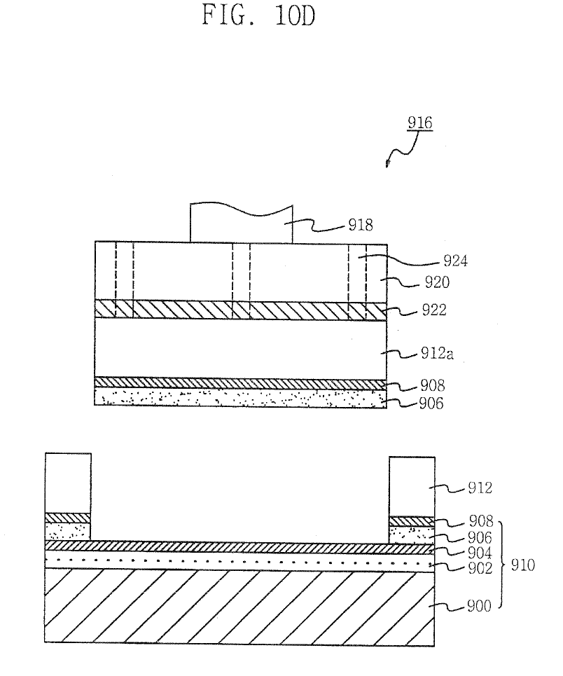

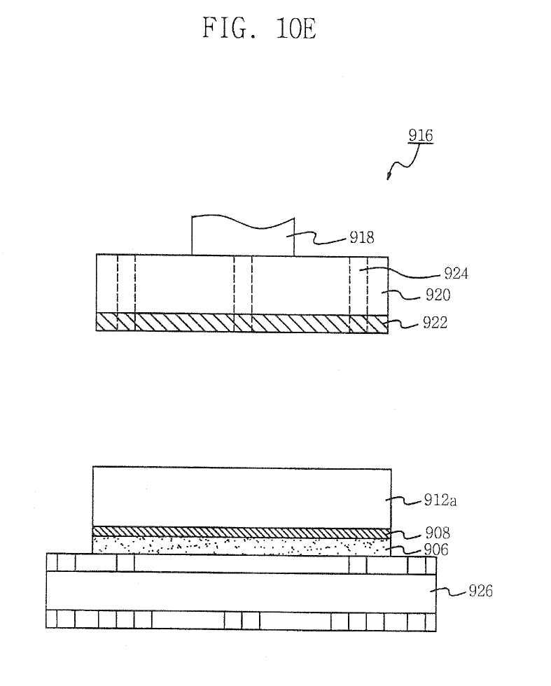

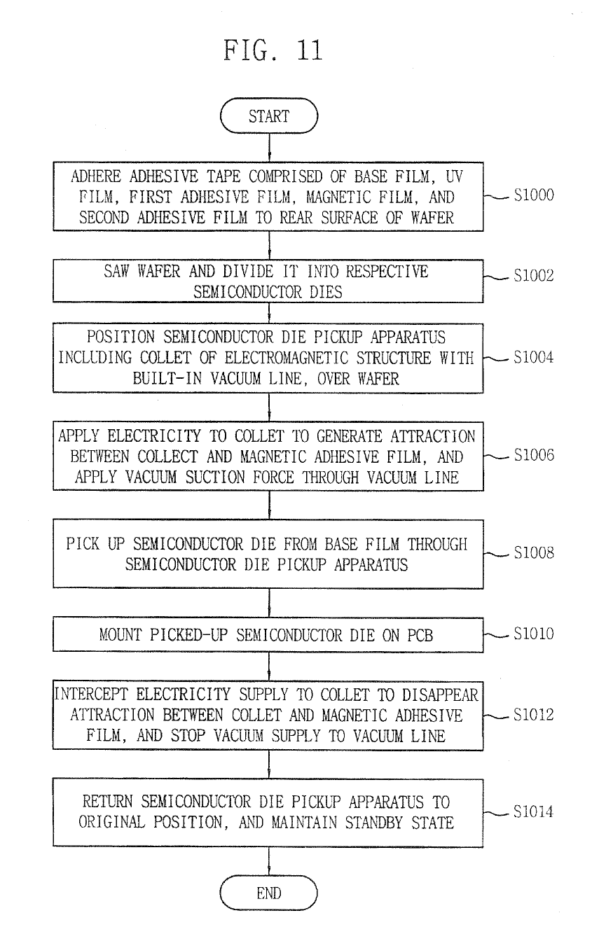

FIG. 10A to 10E illustrate a semiconductor die pickup apparatus and semiconductor die pickup processes according to other example embodiments. FIG. 11 is a flowchart describing some of the processes illustrated in FIGS. 10A to 10E.

With reference to FIGS. 10A and 11, an adhesive tape 910, which is constructed of a base film 900, UV film 902, a first adhesive film 904, a magnetic adhesive film 906, and a second adhesive film 908, adheres to a rear face of wafer 912, in a step S1000. The base film 900 has a shape of dicing tape, and the UV film 902 is a material layer formed of a very sticky material to increase an adhesive force between the base film 900 and the first adhesive film 904. The second adhesive film 908 functions to strongly fix the wafer 912 to the base film 900. The magnetic adhesive film 906 is disposed between the first adhesive film 904 and the second adhesive film 908.

In forming the magnetic adhesive film 906, the first adhesive film 904 is formed on the UV film 902. Then, a general adhesive film is formed on the first adhesive film 904, and then ferrite material surrounded by material containing O₂, as a magnetic substance, is injected thereinto, and then cured at a predetermined temperature. The ferrite material is oxidized in the cured step and so has a property of paramagnetic substance. Thus, the general adhesive film is changed into magnetic adhesive film 906 having the properties of paramagnetic substance. The oxidized ferrite material acts as magnetic filler so that the general adhesive filler has paramagnetic properties. The ferrite material may be material of electromagnetic structure forming a magnetic field when electricity is applied, such as iron, nickel, cobalt, etc.

On the other hand, the iron, nickel, cobalt, etc. are themselves ferrite material that have ferromagnetic properties. Thus, in alternative example embodiments the properties of ferromagnetic material can be used intact without the cure step.

It was described above that a general adhesive film is formed on the first adhesive film 904 and then ferrite material is injected thereinto to change it into magnetic adhesive film. But, besides such a method, the ferrite material layer may also be formed to a given thickness directly on the first adhesive film 904. In this case, the ferrite material layer may be material layer of an electromagnetic structure, such as iron, nickel, cobalt etc. for forming a magnetic field when electricity is applied.

Referring to FIGS. 10B and 11, a wafer 912 whose rear face adheres to the adhesive tape 910, is sawed along a scribe line of the wafer 912 by using blade. Then, plural semiconductor dies formed on the wafer 912 are separated into respective semiconductor dies along a cut line based on the scribe line as reference number 914, in a step S1002.

Subsequently, to pick up the semiconductor dies 912a separated by the piece along the cut line 914, a semiconductor die pickup apparatus 916 according to an embodiment of the invention is positioned over the wafer 912 in a step S1004. The semiconductor die pickup apparatus 916 comprises a transfer head 918 and a collet 920. The transfer head 918 is connected to a drive device and moves by the piece the semiconductor die to a process equipment for a subsequent process. The collet 920 adheres to a lower end of the transfer head 918, and picks up the sawed semiconductor die 912a. A lower part of the collet 920 may be provided additionally with a protection film 922 formed of soft material to substantially reduce the damage on the semiconductor die. It is herein a characteristic that the collet 920 of the semiconductor die pickup apparatus 916 is formed of magnetizable material. More particularly, the collet 920 is metal material of forming magnetic field when electricity is applied, i.e., iron, nickel or cobalt etc. as electromagnetic material of ferrite group. A plurality of vacuum lines 924 to apply suction to the sawed semiconductor die 912a are formed inside the collet 920.

With reference to FIGS. 10C and 11, semiconductor die pickup apparatus 916 including collet 920 of the electromagnetic structure is positioned over the sawed semiconductor die 912a, and then electricity is applied to the collet 920. Then, the collet 920 of the electromagnetic structure is magnetized, creating an attractive force between the collet 920 and the magnetic adhesive film 906 adhering to the rear face of the wafer 912 as referred by reference character F. Additionally, vacuum is supplied to the vacuum line 924 adapted inside the collet 920. As a result, attractive force between the magnetized collet 920 and the magnetic adhesive film 906 and a vacuum suction force through the vacuum line 924 act on the semiconductor die 912a, in a step S1006.

With reference to FIGS. 10D and 11, when the attractive force acts between the collet 920 of electromagnetic structure and the magnetic adhesive film 906 and when the vacuum suction force through the vacuum line 924 acts, the sawed semiconductor die 912a is picked up by using the transfer head 918 of the semiconductor die pickup apparatus 916, in a step S1008. That is, the magnetic adhesive film 906 is separated from the first adhesive film 904 through the attractive force acting between the collet 920 and the magnetic adhesive film 906, thereby separating the sawed semiconductor die 912a from the base film 900 and picking it up.

Preferably, magnetic filler is evenly distributed in the entire magnetic adhesive film 906. Preferably, magnetism is also evenly generated in the entire collet 920. An even attractive force acts through an entire area of the magnetic adhesive film 906 and the collet 920, and thus an even pickup force acts on the sawed semiconductor die 912a positioned on the magnetic adhesive film 906. Consequently, in picking up semiconductor die 912a by using the semiconductor die pickup apparatus 916, as shown in FIG. 10D, an even detaching force acts on an entire area of the semiconductor die 912a, whereby simply picking up the sawed semiconductor die 912a from the base film 900 does not result in a transformation or crack on the semiconductor die 912a.

Referring to FIGS. 10E and 11, the picked-up semiconductor die 912a is moved to PCB 926 and mounted thereon in a step S1010. Then, electricity input to the collet 920 is intercepted. Next, the vacuum supply to the vacuum line 924 is intercepted in a step S1012. Then, the magnetism of the collet 920 disappears, and the attractive force with the magnetic adhesive film 906 also disappears. Furthermore, the vacuum suction force through the vacuum line 924 disappears. The sawed semiconductor die 912a remains on the PCB 926 and the semiconductor die pickup apparatus 916 returns to the original position and stands by for a subsequent semiconductor die pickup operation in a step S1014.

According to the example embodiments described above, the magnetic adhesive film 906 containing magnetic filler that has a paramagnetic substance, and the collet 920 of electromagnetic structure having an attractive force with the magnetic adhesive film 906 are used, thereby effectively separating the sawed semiconductor die 912a from the base film without causing transformations or cracks. The vacuum line 924 is formed inside the collet 920, thus a pickup effect of the sawed semiconductor die 912a may be doubled as compared with depending only upon the attractive force with the magnetic adhesive film 906.

As described above, according to example embodiments, a magnetic adhesive film containing magnetic filler that has a characteristic of magnetic substance as paramagnetic substance or ferromagnetic substance, is applied thereto as the wafer adhesive tape to fix a sawed semiconductor die. Furthermore, a collet of an electromagnetic structure to which an attractive force with the magnetic adhesive film acts, is employed in a semiconductor die pickup apparatus to pick up the sawed semiconductor die. Consequently, an attractive force evenly acts through an entire area between the collet and the magnetic adhesive film, and thus an even pickup force acts on a semiconductor die positioned on the magnetic adhesive film, thereby effectively separating a semiconductor die from a base film of a wafer adhesive tape without transformation or crack of the semiconductor die and so substantially reducing a pickup error.

Additionally, in a conventional art there is an inconvenience of fabricating a specific semiconductor die pickup apparatus according to the size of semiconductor die. However, according to the example embodiments described above, a semiconductor die pickup apparatus can be fabricated freely without design restraints, i.e., complete flat or round shape etc., to effect at most by a fidelity and working efficiency for semiconductor dies, thereby enhancing the fidelity and working efficiency for semiconductor dies and also providing advantages in costs. In particular for flip chips, a space without pads should remain in a center portion in consideration of a contact for the conventional collet, but a vacuum line like in a conventional art is not required in applying collet of an electromagnetic structure thereto according to embodiments of the invention, thereby miniaturizing a semiconductor die pickup apparatus relative to the conventional pickup apparatus and a greater work efficiency.

Accordingly, according to some embodiments of the invention, an inconvenience of fabricating a specific semiconductor die pickup apparatus according to the size of semiconductor die like in a conventional art can be settled, thereby substantially curtailing costs for manufacturing apparatuses.

Additionally, by also adapting a vacuum line inside a collet of electromagnetic structure according to some example embodiments, a pickup effect for sawed semiconductor dies can be increased compared to depending only upon an attractive force with a magnetic adhesive film.

Though the semiconductor die pickup apparatus and method thereof are described above according to several example embodiments, the configuration of wafer adhesive tape etc. adhering to a rear face of wafer or a semiconductor die pickup apparatus to pick up sawed-semiconductor dies is not limited to the embodiments described above, but may be varied diversely without deviating from the spirit of the invention. For example, the sequence or kinds of total material layers constituting the wafer adhesive tape may be varied. The semiconductor die pickup apparatus according to example embodiments also has a collet that is formed of metal material of an electromagnetic structure instead of a conventional rubber material. Therefore, other constituents may be added to a lower end or upper end of collet while still maintaining the electromagnetic properties in accordance with example embodiments.

As described above, according to some embodiments of the invention, a magnetic adhesive film containing magnetic filler having the properties of magnetic substance is employed as the wafer adhesive tape to fix a sawed semiconductor die. Furthermore, a collet having an electromagnetic structure to which an attractive force with the magnetic adhesive film acts, is employed in a semiconductor die pickup apparatus to pick up the sawed semiconductor dies. Accordingly, attractive force evenly acts through an entire area between the collet and the magnetic adhesive film, and thus an even pickup force acts on a semiconductor die positioned on the magnetic adhesive film, thereby effectively separating a semiconductor die from a base film of a wafer adhesive tape without transformation or crack of the semiconductor die and so substantially reducing pickup error. The inconvenience of fabricating a specific pickup apparatus according to the size of semiconductor dies can also be avoided.

It should be apparent that the invention may be practiced in many ways. What follows are example, non-limiting descriptions of some embodiments.

According to some example embodiments, a semiconductor die pickup apparatus includes a collet unit of electromagnetic structure for generating attractive force between the collet unit and a magnetic adhesive film constituting a wafer adhesive tape adhering to a rear face of wafer. The semiconductor die pickup apparatus further includes a transfer head unit for moving a semiconductor die picked up by the collet unit through a drive of a drive device.

According to some example embodiments, a semiconductor die pickup apparatus includes a wafer adhesive tape including a magnetic adhesive film, adhering to a rear face of wafer to fix a sawed semiconductor die, a collet unit of electromagnetic structure for generating attractive force with a magnetic adhesive film of the wafer adhesive tape, and a transfer head unit for moving the sawed semiconductor die picked up by the collet unit through a drive of a drive device.

According to some example embodiments, a method of picking up a semiconductor die comprises adhering a wafer adhesive tape including a magnetic adhesive film to a rear face of wafer, sawing the wafer whose rear face adheres to the adhesive tape, into respective semiconductor dies, positioning a semiconductor die pickup apparatus over the sawed semiconductor die, the semiconductor die pickup apparatus including a collet unit of electromagnetic structure to generate attractive force with the magnetic adhesive film, and generating a magnetic field in the collet unit by applying electricity to the collet unit, and thus generating an attractive force with the magnetic adhesive film and sucking the semiconductor die by the collet unit.

According to some example embodiments, a semiconductor die pickup method includes adhering a wafer adhesive tape including a base film and a magnetic adhesive film, to a rear face of wafer, sawing the wafer whose rear face adheres to the adhesive tape along a scribe line, into respective semiconductor dies, positioning a semiconductor die pickup apparatus over the sawed semiconductor die, the semiconductor die pickup apparatus including a collet unit of electromagnetic structure to generate attractive force with the magnetic adhesive film, and applying electricity to the collet unit and then generating a magnetic field in the collet unit, and thus generating an attractive force with the magnetic adhesive film and separating the semiconductor die from the base film.

It will be apparent to those skilled in the art that modifications and variations can be made to the example embodiments described above without deviating from the spirit or scope of the invention. Thus, it is intended that the present invention cover any such modifications and variations of this invention provided they come within the scope of the appended claims and their equivalents. Accordingly, these and other changes and modifications are seen to be within the true spirit and scope of the invention as defined by the appended claims.

In the drawings and specification, there have been disclosed typical embodiments of the invention and, although specific terms are employed, they are used in a generic and descriptive sense only and not for purposes of limitation, the scope of the invention being set forth in the following claims.

What is claimed is:

1. An apparatus for picking up a semiconductor die, comprising:
a collet unit of electromagnetic structure for generating an attractive force between the collet unit and a wafer adhesive tape that is disposed on a rear face of a wafer, the wafer adhesive tape including a magnetic adhesive film; and
a transfer head unit attached to the collet unit, the transfer head unit structured to move the collet unit and the semiconductor die.

2. The apparatus of claim 1, wherein the collet unit further comprises a protection layer to protect the semiconductor die, the protection layer disposed on a surface of the collet unit.

3. The apparatus of claim 1, wherein the collet unit further comprises a vacuum line to apply suction to the semiconductor die, the vacuum line disposed inside the collect unit.

4. The apparatus of claim 1, wherein the wafer adhesive tape further comprises:
a base film; and
a UV film disposed on the base film, wherein the magnetic adhesive film is disposed on the UV film.

5. The apparatus of claim 4, wherein the magnetic adhesive film includes a magnetic filler, the magnetic filler including a ferrite material.

6. The apparatus of claim 5, wherein the ferrite material comprises iron.

7. The apparatus of claim 6, wherein the collet unit comprises a metal material that forms a magnetic field when electricity is applied.

8. The apparatus of claim 7, wherein the metal material is an electromagnetic material of a ferrite group.

9. The apparatus of claim 8, wherein the metal material comprises at least one selected from the group consisting of iron, nickel, and cobalt.

10. An apparatus for picking up a semiconductor die, comprising:
an electromagnetic collet unit configured to selectively generate an attractive force between the electromagnetic collet unit and a magnetic wafer adhesive tape disposed on a surface of the semiconductor die; and
a transfer head unit attached to the electromagnetic collet unit, the transfer head unit structured to move the semiconductor die picked up by the collet unit through a drive of a drive device.

11. The apparatus of claim 10, the magnetic wafer adhesive tape comprising:
a base film;
a UV film disposed on the base film; and
a magnetic adhesive film disposed on the UV film.

12. The apparatus of claim 11, wherein the magnetic adhesive film comprises at least one selected from the group consisting of a ferromagnetic material and a paramagnetic material.

13. The apparatus of claim 12, wherein the ferromagnetic material comprises nickel.

14. The apparatus of claim 10, wherein the electromagnetic collet unit comprises a metal material from a ferrite group.

15. The apparatus of claim 14, wherein the metal material comprises at least one selected from the group consisting of iron, nickel, and cobalt.

16. A method of separating a semiconductor die from a wafer and picking up the semiconductor die, the method comprising:
adhering a wafer adhesive tape that includes a magnetic adhesive film to a rear face of the wafer;
sawing the wafer to separate the semiconductor die from the wafer;
positioning a collet unit over the semiconductor die, the collet unit having an electromagnetic structure; and
applying electricity to the collet unit to generate a magnetic field that attracts the magnetic adhesive film and holds the semiconductor die against the collet unit.

17. The method of claim 16, wherein adhering the wafer adhesive tape to the rear face of the wafer comprises placing a magnetic filler within the magnetic adhesive film, the magnetic filler comprising a ferrite material.

18. The method of claim 17, wherein placing the magnetic filler within the magnetic adhesive film comprises placing cobalt within the magnetic adhesive film.

19. The method of claim 16, wherein the electromagnet comprises a metal material from a ferrite group.

20. The method of claim 16, wherein the metal material comprises at least one selected from the group consisting of iron, nickel, and cobalt.

21. A method of picking up a semiconductor die, the method comprising:
adhering a wafer adhesive tape to a rear face of a wafer, the wafer adhesive tape including a base film and a magnetic adhesive film;
sawing the wafer along a scribe line to separate the wafer into semiconductor dies;
positioning a semiconductor die pickup apparatus over the semiconductor dies, the semiconductor die pickup apparatus including a collet unit having an electromagnetic structure to generate an attractive force with the magnetic adhesive film; and
applying electricity to the collet unit to generate an attractive force between the collet unit and the magnetic adhesive film and separate the semiconductor dies from the base film.

22. The method of claim 21, wherein the wafer adhesive tape further comprises a UV film disposed on the base film, and the magnetic adhesive film is disposed on the UV film.

23. The method of claim 22, wherein the wafer adhesive tape further comprises a first adhesive film interposed between the UV film and the magnetic adhesive film and a second adhesive film disposed on the magnetic adhesive film.

24. The method of claim 21, further comprising:
mounting the semiconductor die picked up by the collet unit on a PCB (Printed Circuit Board) by using a transfer head; and
intercepting an electrical supply to the collet unit to eliminate a magnetic field generated by the collet unit.

25. The method of claim 21, further comprising applying suction to the semiconductor dies simultaneously with the attractive force.
